(19) United States
(12) Patent Application Publication
(10) Pub. No.: US 2013/0334948 A1
(43) Pub. Date: Dec. 19, 2013

(54) SURFACE CONTACT CARD HOLDER FOR ELECTRONIC DEVICE

(71) Applicants: SHENZHEN FUTAIHONG PRECISION INDUSTRY CO., LTD., Shenzhen (CN); FIH (HONG KONG) LIMITED, Kowloon (HK)

(72) Inventors: HUAN-CHANG CHUNG, Shindian (TW); JING XIA, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/728,109

(22) Filed: Dec. 27, 2012

(30) Foreign Application Priority Data
Jun. 18, 2012 (CN) 2012102007735

(51) Int. Cl. H05K 7/14

(52) U.S. Cl. CPC H05K 7/1461
USPC 312/333

(57) ABSTRACT

A holder for a surface contact card includes a receiving frame, a magnetic member, and a tray. The receiving member defines a first receiving space and a latching space. The magnetic member is latched in the latching space. The tray is slidably received in the first receiving space of the receiving frame and is magnetically attracted by the magnetic member. The tray defines a second receiving space configured for receiving the surface contact card.

### BACKGROUND

1. Technical Field

The present disclosure generally relates to card use in electronic devices, and particularly, to a surface contact card holder for an electronic device.

2. Description of Related Art

Surface contact cards having special circuits are widely used in portable electronic devices to enhance or specialize the functions of the portable electronic devices. For example, a subscriber identity module (SIM) card in a mobile phone can dedicate the mobile phone's functions to the SIM card owner. By changing SIM cards, a single mobile phone can be used by many different SIM card owners as a personal phone.

Although surface contact card holders may be simple, it can be difficult for the surface contact card to be removed from the surface contact card holder.

Therefore, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the surface contact card holder. Moreover, in the drawings, like reference numerals designate corresponding parts throughout the several views.

FIG. 1 is an exploded, isometric view of one part of an electronic device with a surface contact card holder in accordance with an exemplary embodiment.

FIG. 2 is similar to FIG. 1, but shown from another aspect.

FIG. 3 is an assembled isometric view of the surface contact card holder.

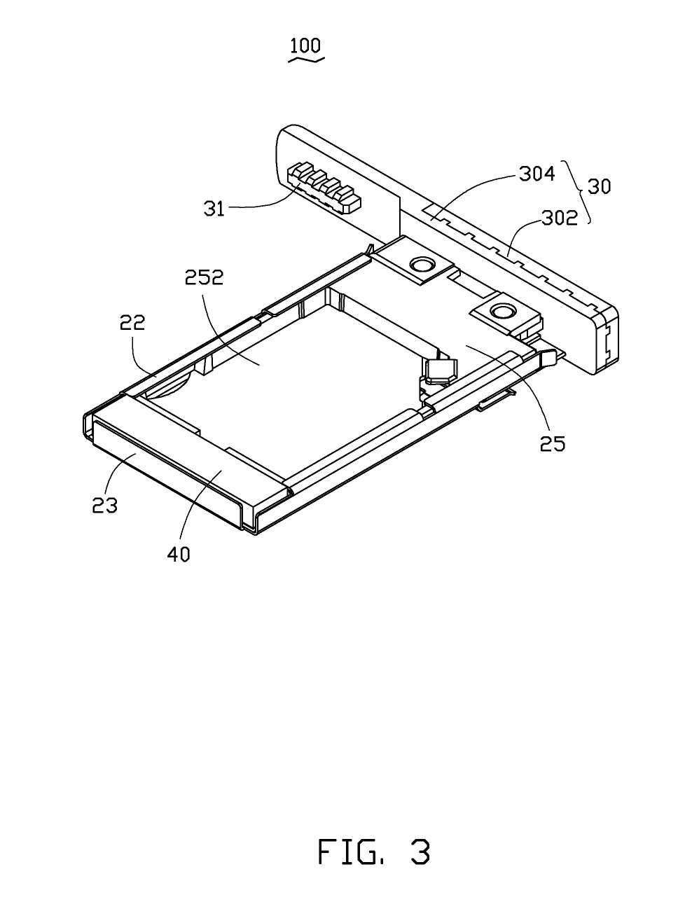

FIG. 4 is an isometric view of the assembled surface contact card holder assembled on the electronic device.

FIG. 5 is a cross sectional view of the surface contact card holder shown in FIG. 4 taken along line V-V.

FIG. 6 is an open schematic view of the surface contact card holder.

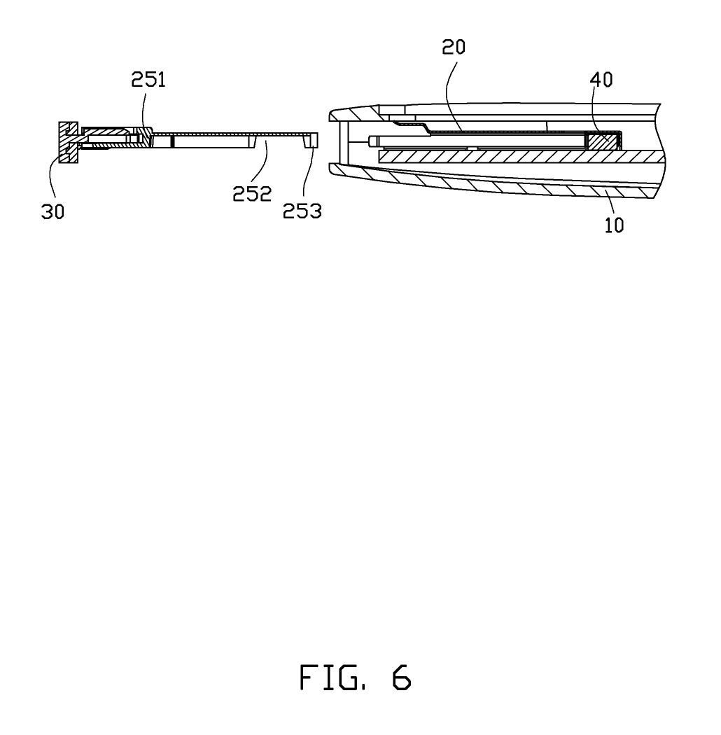

### DETAILED DESCRIPTION

The disclosed surface contact card holder can seat surface contact cards such as SIM cards, compact flash cards, and multimedia cards, for example. The disclosed electronic device, shown in the exemplary embodiment as a mobile phone, can alternatively be a personal digital assistant, camera, recorder, or other device remaining well within the scope of the disclosure.

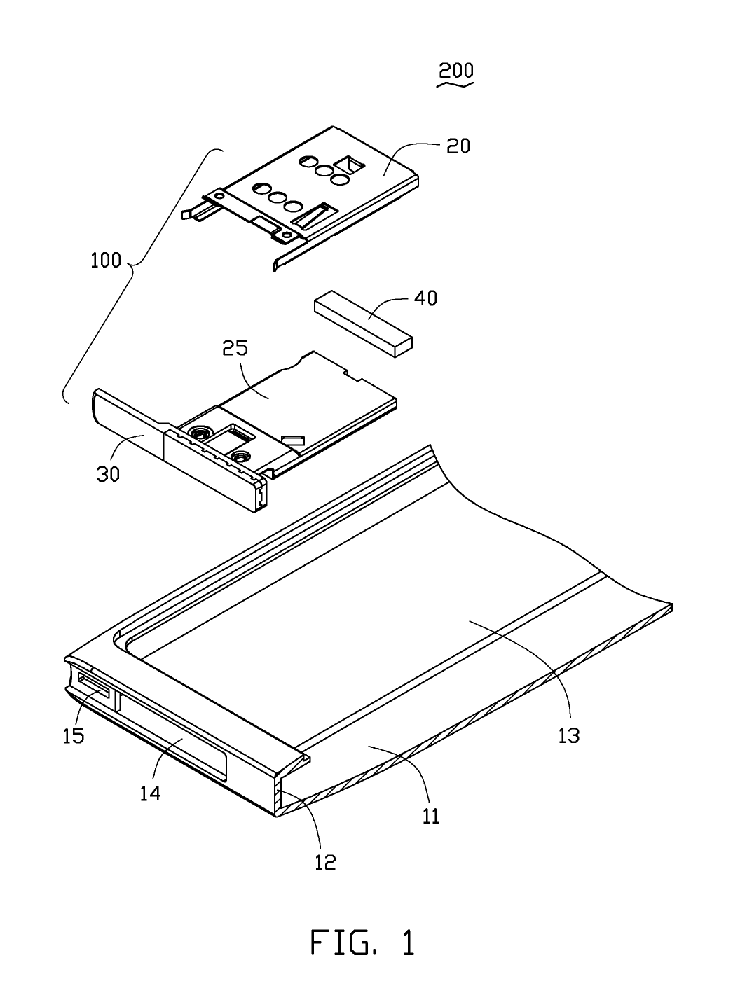

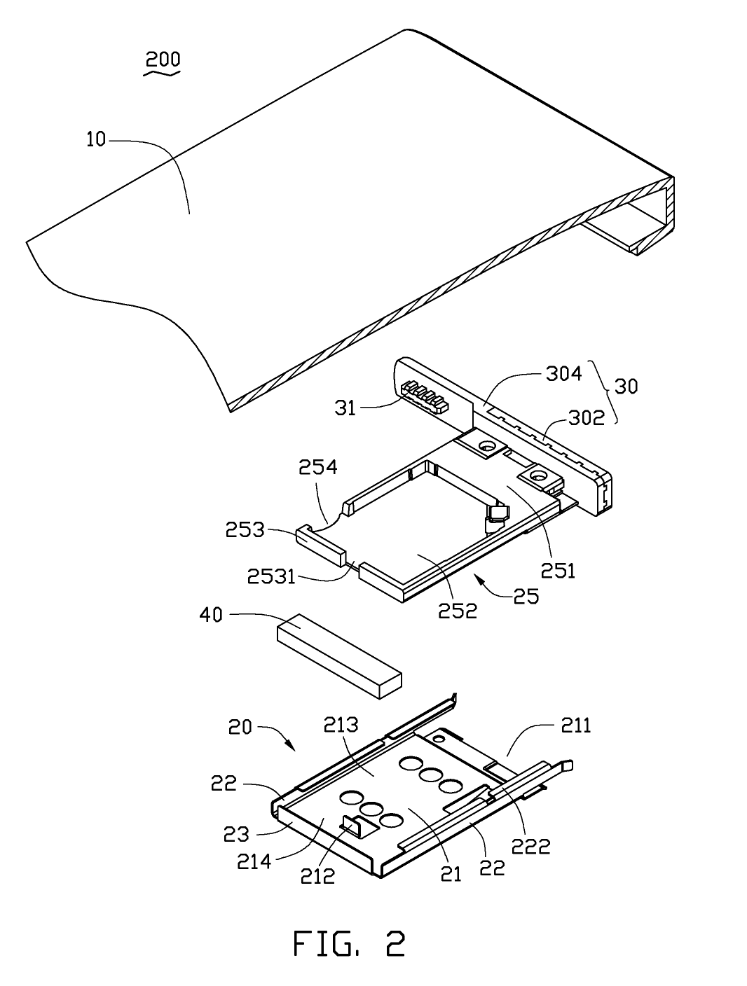

FIGS. 1 and 2 show a surface contact card holder 100 of the embodiment. The surface contact card holder 100 is used in an electronic device 200 and is configured for receiving a surface contact card. The electronic device 200 comprises a main body 10. The surface contact card holder 100 comprises a receiving frame 20, a tray 25, an operation button 30, and a magnetic member 40. The tray 25 is slidably received on the receiving frame 20, and is positioned on the receiving frame 20 with the magnetic member 40. The operation button 30 is located at one end of the tray 25 and is configured for operating the tray 25.

The main body 10 comprises a base 11 and an end portion 12 integrally formed together. A printed circuit board 13 is positioned on the base 11. The end portion 12 defines a through hole 14 and a latching groove 15. The tray 25 can be extended to the inside of the main body 10 via the through hole 14. The latching groove 15 is configured for latching the operation button 30.

The receiving frame 20 is configured for being attached to the printed circuit board 13. The receiving frame 20 comprises a bottom plate 21, two opposite side edges 22, and an end edge 23. The side edges 22 perpendicularly extend from opposite sides of the bottom plate 21. A plurality of flanges 222 horizontally extend from the opposite side edges 22, and are parallel to the bottom plate 21. An entrance 211 is defined at one end of the receiving frame 20. The end edge 23 with the side edges 22 and the bottom plate 21 cooperatively define a first receiving space 213 for receiving the tray 25. An extending tab 212 is located on the bottom plate 21 adjacent to the end edge 23. A latching space 214 is defined between the extending tab 212 and the end edge 23 for receiving the magnetic member 40.

The tray 25 is made of metal, and is formed by punching to a predetermined shape. The metal material is used as it can be magnetically attracted. The tray 25 comprises a tray body 251 defining a second receiving space 252 for receiving a surface contact card. The tray body 251 has an end wall 253 defining a cutout 2531. One side of the tray body 251 defines a notch 254 for conveniently gripping the surface contact card in position.

The operation button 30 is located at one end of the tray body 251. The operation button 30 comprises a first material body 302 and a second material body 304 integrally embedded together. In this exemplary embodiment, the first material body 302 is made of hard material such as plastics and the second material body 304 is made of rubber. The first material body 302 is mounted (e.g., holt-melt) on the tray body 251. The first material body 302 corresponds to the through hole 14, and the second material body 304 corresponds to the latching groove 15. A block 31 is formed at an inside surface of the second material body 304 configured for being plugged into the latching groove 15.

The magnetic member 40 is a bar-shaped magnet, and is configured for being mounted on the latching space 214 for magnetically attracting the tray 25. In this exemplary embodiment, the magnetic member 40 is mounted on the latching space 214 by double-side adhesive.

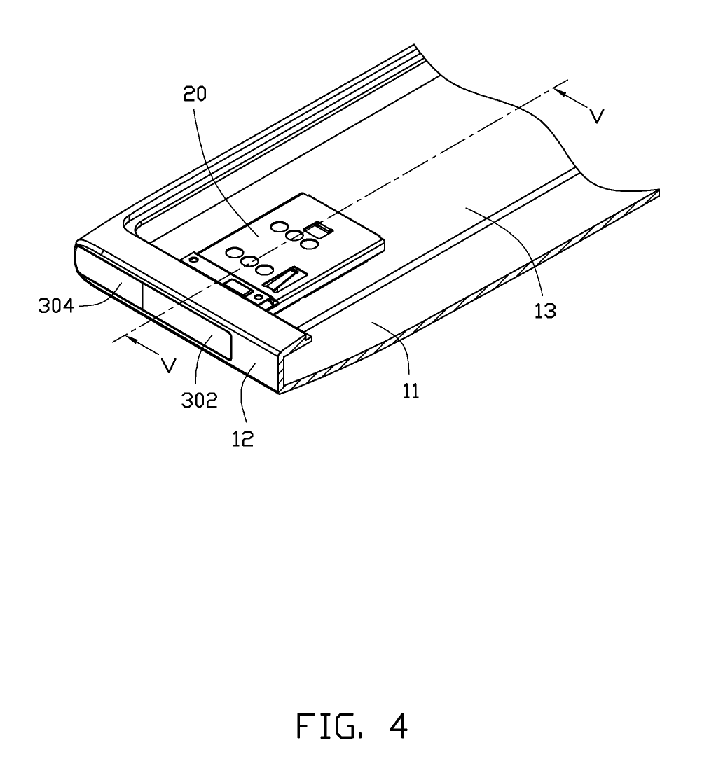

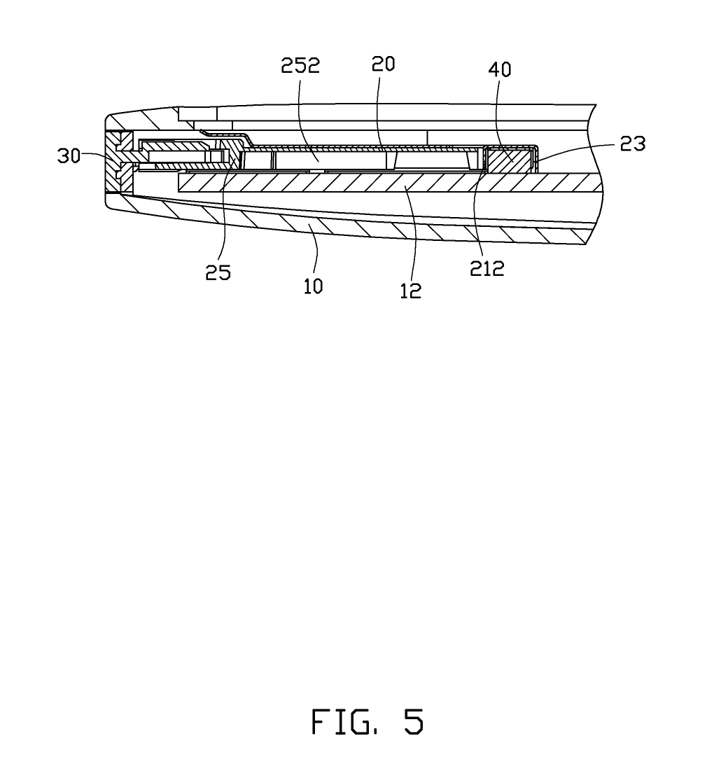

Referring to FIGS. 4 and 5, to assemble the surface contact card holder 100, the receiving frame 20 is mounted on the printed circuit board 13 by welding or fasteners. The entrance 211 is aligned with the through hole 14 of the main body 10. The tray 25 is slidably received into the first receiving space 213 of the receiving frame 20 through the entrance 211 and the through hole 14 until the extending tab 212 is latched into the cutout 2531. The magnetic member 40 magnetically attracts the end wall 253, and thus, the tray 25 is positioned on the receiving frame 20. The operation button 30 covers the through hole 14 and the latching groove 15, and the block 31 is plugged in the latching groove 15.

To insert the surface contact card into the surface contact card holder 100, the second material body 304 is gripped, and is pulled toward the outside of the tray 25. The block 31 moves out of the latching groove 15, and the tray 25 is pulled away from the receiving frame 20 for allowing the surface contact card to be inserted into the second receiving space 252 of the tray 25. This structure allows the surface contact card holder 100 to be held steadily in the electronic device 200.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A holder for a surface contact card, comprising:
a receiving frame defining a first receiving space and a latching space;
a magnetic member latched in the latching space;
a tray slidably received in the first receiving space of the receiving frame and magnetically attracted by the magnetic member, the tray defining a second receiving space configured for receiving the surface contact card.

2. The holder as claimed in claim 1, wherein the magnetic member is a bar-shaped magnet.

3. The holder as claimed in claim 1, wherein the receiving frame comprises a bottom plate, two opposite side edges, and an end edge; the end edge with the two opposite side edges and the bottom plate cooperatively define the first receiving space; and an entrance is defined at one end of the receiving frame.

4. The holder as claimed in claim 3, wherein the two opposite side edges perpendicularly extend from opposite sides of the bottom plate, a plurality of flanges horizontally extend from the two opposite side edges and are parallel to the bottom plate.

5. The holder as claimed in claim 3, wherein an extending tab is located on the bottom plate, adjacent to the end edge; and the latching space is defined between the extending tab and the end edge, for receiving the magnetic member.

6. The holder as claimed in claim 5, wherein the tray has an end wall defining a cutout, and the extending tab is received in the cutout.

7. An electronic device comprising a holder for a surface contact card, the holder mounted on the electronic device and comprising:
a receiving frame defining a first receiving space;
a magnetic member mounted on the receiving frame;
a tray slidably received in the first receiving space of the receiving frame and magnetically attracted by the magnetic member, the tray defining a second receiving space configured for receiving the surface contact card.

8. The electronic device as claimed in claim 7, wherein the receiving frame comprises a bottom plate, two opposite side edges, and an end edge; the end edge with the two opposite side edges and the bottom plate cooperatively define the first receiving space, and an entrance is defined at one end of the receiving frame.

9. The electronic device as claimed in claim 8, wherein an extending tab is located on the bottom plate, adjacent to the end edge; and a latching space is defined between the extending tab and the end edge for receiving the magnetic member.

10. The electronic device as claimed in claim 9, further comprising an operation button, wherein the electronic device comprises a main body, the operation button is located at one end of the tray, the operation button comprises a first material body and a second material body integrally embedded together, and a block is formed at an inside surface of the second material body, and is latched in the main body.
